(19) United States
(12) Patent Application Publication
(10) Pub. No.: US 2007/0175395 A1
(43) Pub. Date: Aug. 2, 2007

(54) Semiconductor device manufacturing equipment including a vacuum apparatus and a method of operating the same

(76) Inventor: Sang-Do Oh, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/698,031

(22) Filed: Jan. 26, 2007

(30) Foreign Application Priority Data
Feb. 1, 2006 (KR) 2006-0009541

(51) Int. Cl. B65H 1/00; C23C 16/00; H01L 21/677; C23F 1/00; H01L 21/306

(52) U.S. Cl. 118/719; 414/217; 414/805; 414/939; 118/715; 118/733; 156/345.31; 156/345.32

(57) ABSTRACT

A vacuum apparatus includes a first isolation chamber, a second isolation chamber, a vacuum source configured to extract air from the first and second isolation chambers, and an isolation valve unit, wherein the isolation valve unit is configured to close a flow path between the vacuum source and the first isolation chamber before opening a flow path between the vacuum source and the second isolation chamber when the first isolation chamber is in a vacuum state and the second isolation chamber is at a pressure higher than that of the first isolation chamber.

### BACKGROUND OF THE INVENTION

1. Field of the Invention

The present invention relates to semiconductor device manufacturing equipment. More particularly, the present invention relates to semiconductor device manufacturing equipment including a vacuum apparatus and a method of operating the same.

2. Description of the Related Art

Generally, semiconductor devices may be fabricated by depositing one or more thin layers on a substrate, e.g., a semiconductor substrate, with the layers serving various functions. The layers may be patterned to form various circuit structures. In the fabrication of semiconductor devices, there may be many unit processes. For example, processes may include an impurity ion implantation process, e.g., for implanting impurity ions of group 3B, such as boron (B), or group 5B, such as phosphorus (P) or arsenic (As), into the semiconductor substrate. Other processes may include a thin layer deposition process for forming a material layer on the semiconductor substrate, an etching process for defining the material layer of the semiconductor substrate in a desired pattern, and a planarization process, e.g., chemical mechanical polishing (CMP), for planarizing an entire surface of the semiconductor substrate after depositing a layer, such as an interlayer insulating layer, etc. Still other process may include, e.g., a cleaning process for removing impurities from the wafer or a chamber, etc.

Unit processes may be repeated several times to fabricate the semiconductor devices, and may be performed using various pieces of manufacturing equipment. In the semiconductor device manufacturing equipment, contaminants in air, particles such as polymers generated during fabrication processes, etc., may have a significant impact on reliability and yield of the semiconductor devices. Hence, semiconductor manufacturing equipment may be provided with a process chamber that is isolated from the outside, and which may be kept under a vacuum atmosphere in order to maintain the level of contaminants as low as possible.

To pump the process chamber from an atmospheric pressure to a vacuum whenever a wafer is introduced into the process chamber, a long lead time may be required, which is undesirable. Accordingly, the semiconductor manufacturing equipment may include a load lock chamber in which a wafer cassette, in which a plurality of wafers to be introduced into the process chamber are mounted, is located and in which the level of vacuum is similar to that of the process chamber. The semiconductor manufacturing equipment may also include a transfer chamber provided with a robotic arm for taking a wafer out of the wafer cassette in the load lock chamber and transferring the wafer to the process chamber. In order to improve operation efficiency, the semiconductor manufacturing equipment having the process chamber, the load lock chamber, and the transfer chamber may be designed as a cluster, where one or more load lock chambers and process chambers are disposed around the transfer chamber, e.g., in a circular fashion.

In order to improve the reliability and yield of semiconductor devices, it is important to maintain a high level of cleanliness inside the equipment, e.g., in the process chamber in which the semiconductor device manufacturing process is performed. To this end, the equipment may be pumped using a pumping apparatus such as a vacuum pump. In a cluster of semiconductor device manufacturing equipment, two neighboring load lock chambers may share one vacuum pump. The neighboring load lock chambers, and each of the load lock chambers and the vacuum pump, may be interconnected by an exhaust line, as illustrated in FIG. 1.

Referring to FIG. 1, a load lock chamber A 10 and a load lock chamber B 12 may be provided with an exhaust line 14. A purge gas supply 15 and a vacuum pump 16 may be connected to the load lock chambers A and B, 10 and 12, via the exhaust line 14, which may be arranged at front and rear ends, respectively, of the load lock chambers A and B, 10 and 12. The front and rear ends of the load lock chambers A and B, 10 and 12, may be provided with isolation valves for opening and closing the exhaust line 14, e.g., isolation valves 18a, 18b, 18c and 18d located at the front end of load lock chamber A 10, the rear end of load lock chamber A 10, the front end of load lock chamber B 12, and the rear end of load lock chamber B 12, respectively.

A purge gas, e.g. nitrogen (N₂), may be supplied from the purge gas supply 15 via the exhaust line 14 into the load lock chambers A and B, 10 and 12. The load lock chambers A and B, 10 and 12 supplied with the purge gas may be pumped to a vacuum state by the vacuum pump 16. The load lock chambers 10 and 12 may be selectively pumped and maintained at a predetermined pressure, i.e., vacuum, using the isolation valves 18a, 18b, 18c, and 18d.

In the exhaust structure illustrated in FIG. 1, a momentary eddy may be generated by mutual influence of the load lock chamber A 10 and the load lock chamber B 12, whereby particles may be generated. For example, where the load lock chamber B 12 is to be pumped to a vacuum while the load lock chamber A 10 is maintained at a vacuum, the load lock chamber A 10 may be in a vacuum state while the load lock chamber B 12 is in an atmospheric pressure state, and the isolation valves 18c and 18d may be opened at the same time while the isolation valves 18a and 18b may be closed at the same time, such that only the load lock chamber B 12 is pumped by the vacuum pump 16 while the load lock chamber A 10 continues to maintain a vacuum. However, the opening of the isolation valve 18d and the closing of the isolation valve 18b may be mismatched in timing. That is, before the isolation valve 18b isolating the load lock chamber A 10 is fully locked, the load lock chamber B 12 may be pumped. When the isolation valve 18d is opened in the state in which the isolation valve 18b is not completely closed, an atmospheric pressure of air in the load lock chamber B 12 may flow into the load lock chamber A 10 via the exhaust line 14. As a result, the pressure in the load lock chamber A 10 may increase rapidly, thereby generating an eddy such that particles are dispersed in the load lock chamber A 10.

If particles are generated in a load lock chamber, they may attach to a standby wafer that is waiting in the load lock chamber. Thus, the wafer may be contaminated and adverse effects may result, e.g., the semiconductor device may exhibit poor reliability, yield may be low, etc. Further, the particles may attach to the robotic arm used to withdraw the wafer from the load lock chamber. When the wafer is transferred by the robotic arm, the transfer chamber and the process chamber may be exposed to such contamination as well, which would necessitate performing a cleaning process on the load lock chamber, the transfer chamber, the process chamber, and the robotic arm. The need for cleaning may lead to a shortened preventive maintenance period of the whole semiconductor device manufacturing equipment, which may have a negative impact on productivity.

### SUMMARY OF THE INVENTION

The present invention is therefore directed to semiconductor device manufacturing equipment including a vacuum apparatus, and a method of operating the same, which substantially overcome one or more of the problems due to the limitations and disadvantages of the related art.

It is therefore a feature of an embodiment of the present invention to provide a vacuum apparatus for semiconductor device manufacturing equipment that is configured to prevent placing a pressure chamber in flow communication with a relatively lower pressure chamber, and a method of operating the same.

It is therefore another feature of an embodiment of the present invention to provide a vacuum apparatus for semiconductor device manufacturing equipment that is configured to isolate a pressure chamber before placing a relatively higher pressure chamber in flow communication with a shared exhaust line.

At least one of the above and other features and advantages of the present invention may be realized by providing a vacuum apparatus including a first isolation chamber, a second isolation chamber, a vacuum source configured to extract air from the first and second isolation chambers, and an isolation valve unit, wherein the isolation valve unit is configured to close a flow path between the vacuum source and the first isolation chamber before opening a flow path between the vacuum source and the second isolation chamber when the first isolation chamber is in a vacuum state and the second isolation chamber is at a pressure higher than that of the first isolation chamber.

The vacuum source may be connected to the first and second isolation chambers by exhaust lines, and the isolation valve unit may include isolation valves configured to open and close the exhaust lines, an isolation valve controller for controlling the opening and closing of the isolation valves, air supplies configured to supply air to the isolation valves according to an isolation valve opening signal from the isolation valve controller, and air dischargers configured to exhaust the air supplied to the isolation valves according to an isolation valve closing signal from the isolation valve controller.

The isolation valves may include pneumatic regulators that are opened and closed by air from the air supplies, and vacuum regulators that are opened and closed according to whether the pneumatic regulators are opened and closed, respectively. The air supplies and the air dischargers may be connected to the pneumatic regulators via valves. The valves may be solenoid valves that are configured to alternately provide and block air from the air supplies to the pneumatic regulators. Signal lines may connect the isolation valve controller to the valves, and the valves may alternately provide and block air from the air supplies in correspondence with signals provided by the isolation valve controller.

The vacuum apparatus may further include forced air dischargers configured to forcibly exhaust air existing between the isolation valves and the air supplies according to the isolation valve closing signal. The air supplies and the air dischargers may be connected to the pneumatic regulators via valves, and the forced air dischargers may be connected to the valves. Signal lines may connect the isolation valve controller to the pneumatic regulators. Signal lines may connect the isolation valve controller to the isolation valves, the air dischargers, and valves disposed between the air supplies and respective isolation valves. The isolation chambers may be load lock chambers.

At least one of the above and other features and advantages of the present invention may further be realized by providing a method of operating a semiconductor device manufacturing equipment having a vacuum apparatus that includes a plurality of chambers having different pressure states, the method including closing a first exhaust line connected to a first chamber having a degree of vacuum higher than that of the other chambers among the plurality of chambers, and, after the closing of the first exhaust line, opening a second exhaust line connected to a second chamber having a pressure higher than that of the first chamber.

The method may further include checking a closed state of the first exhaust line. The closing of the first exhaust line may include providing a close signal from an isolation valve controller to a first valve, the close signal causing the first valve to stop a supply of air from a first air supply to a first isolation valve so as to cause the first isolation valve to close the first exhaust line. The closing of the first exhaust line may further include forcibly exhausting air from the first valve using a first forced air discharger connected to the first valve. The opening of the second exhaust line may include supplying air from a second air supply to a second valve, and using the air from the second air supply to open the second valve between the second air supply and a second isolation valve so as to cause the second isolation valve to open the second exhaust line.

At least one of the above and other features and advantages of the present invention may still further be realized by providing a method of operating a semiconductor device manufacturing equipment having a vacuum apparatus that includes a plurality of chambers having different pressure states, the method including simultaneously performing closing a first exhaust line connected to a first chamber having a degree of vacuum higher than that of the other chambers among a plurality of chambers, and opening a second exhaust line connected to a second chamber having a pressure higher than that of the first chamber.

The closing of the first exhaust line connected to the first chamber may include stopping a supply of air from a first air supply to a first isolation valve, using a first forced air discharger to forcibly exhaust air inside a first valve provided between the first air supply and the first isolation valve, and closing the first valve to as to cause the first isolation valve to close the first exhaust line. The opening of the second exhaust line may include exhausting air existing between the first air supply and the first isolation valve, and using the exhausted air from the first air supply to open a second valve between a second air supply and a second isolation valve so as to cause the second isolation valve to open the second exhaust line.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a schematic structure of an exhaust line for a pair of load lock chambers;

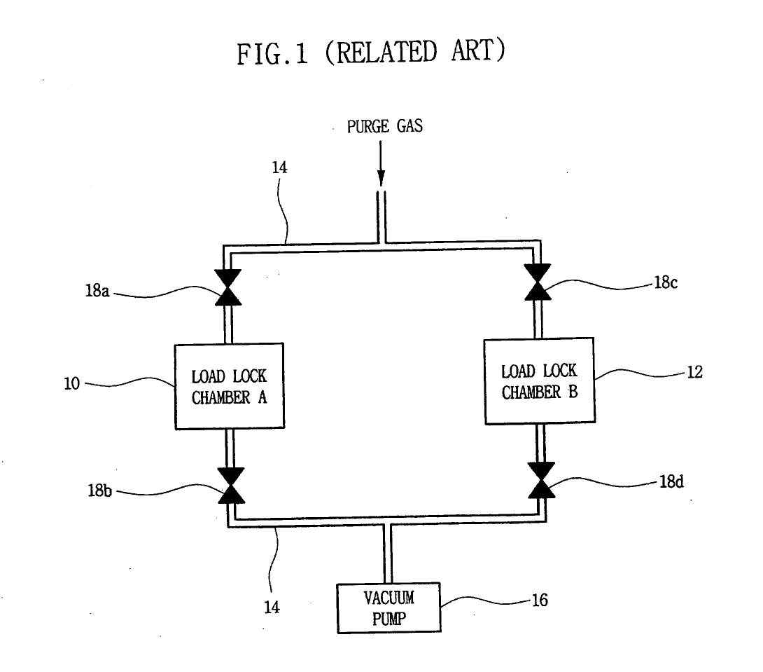

FIG. 2 illustrates a cluster type of semiconductor device manufacturing equipment in accordance with an exemplary embodiment of the present invention;

FIG. 3 illustrates a detailed structure of a load lock chamber of FIG. 2;

FIG. 4 illustrates a block diagram of an isolation valve unit according to an exemplary embodiment of the present invention;

FIG. 5 illustrates a flowchart of a method of operating the isolation valve unit of FIG. 4;

FIG. 6 illustrates a block diagram of an isolation valve unit according to another exemplary embodiment of the present invention; and

FIG. 7 illustrates a flowchart of a method of operating the isolation valve unit of FIG. 6.

### DETAILED DESCRIPTION OF THE INVENTION

Korean Patent Application No. 10-2006-0009541, filed on Feb. 1, 2006, and entitled: “Vacuum Apparatus of Semiconductor Device Manufacturing Equipment and Vacuum Method Using the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, dimensions may be exaggerated for clarity of illustration. Like reference numerals refer to like elements throughout.

As used herein, the term “air” is to be interpreted broadly, and is not limited to atmospheric air. In particular, the term “air” is used generically to describe a gas contained in chambers, connections, etc., of the semiconductor processing equipment described herein. The gas may be composed of a single component, e.g., nitrogen (N₂) or argon (Ar), mixtures thereof, atmospheric air, etc., and may be at pressures above or below atmospheric pressure, including high vacuum states of, e.g., 10⁻⁶ Torr.

With the rapid development of the information telecommunication field and the rapid popularization of information media such as computers, semiconductor devices are being rapidly developed. The semiconductor devices may be required to provide high-speed operation as well as to have mass storage capacity. Further, due to a tendency toward high-density integration and high capacity, each unit element forming a memory cell of a semiconductor device may be reduced in size. As the size of the unit element is reduced, a fabrication process margin may also be reduced. Accordingly, unit processes for fabricating the semiconductor device may require high precision.

One such high precision process involves the use of plasma in order to precisely perform various unit processes such as a thin layer deposition process, an etching process and so on. A process chamber in which the process is substantially performed, a load lock chamber in which at least one wafer to be processed is on standby, and a transfer chamber in which the wafer is transferred may be required to maintain a constant level of pressure. Typically, the process chamber, the load lock chamber, and transfer chamber maintain the required pressure level using a vacuum pump.

An embodiment of the present invention is directed to an isolation valve unit for controlling pressure, e.g., inside a load lock chamber of semiconductor device manufacturing equipment. The isolation valve unit may be adapted to be opened or closed with more rapidity than a conventional vacuum control system, so that an eddy may be prevented from being generated in the load lock chamber. This momentary eddy may be conventionally generated when relatively high pressure air is introduced into the load lock chamber. By preventing the eddy, a probability of generating particles in the load lock chamber can be reduced. Thus, conventional problems of the wafer that is on standby in the load lock chamber, such as wafer loss, the decrease of the preventative maintenance period etc., may be reduced or eliminated.

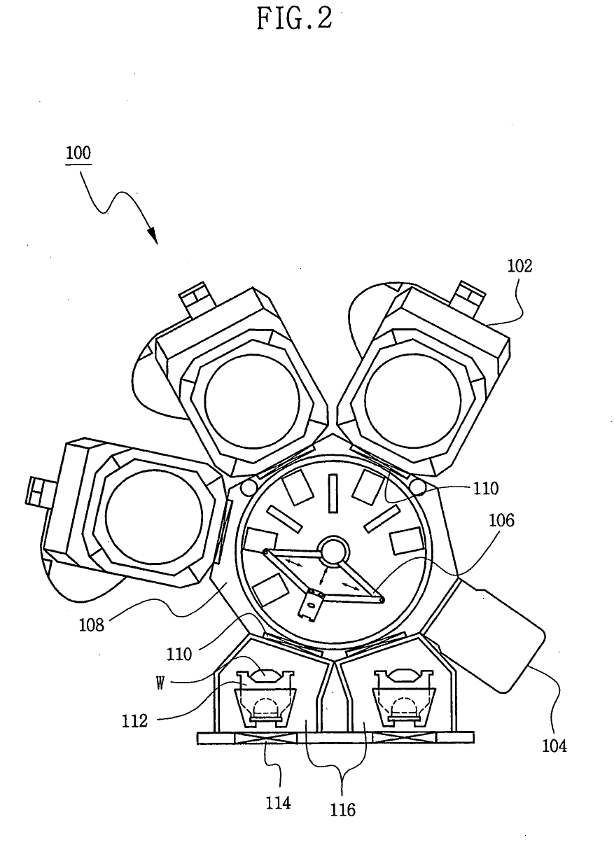

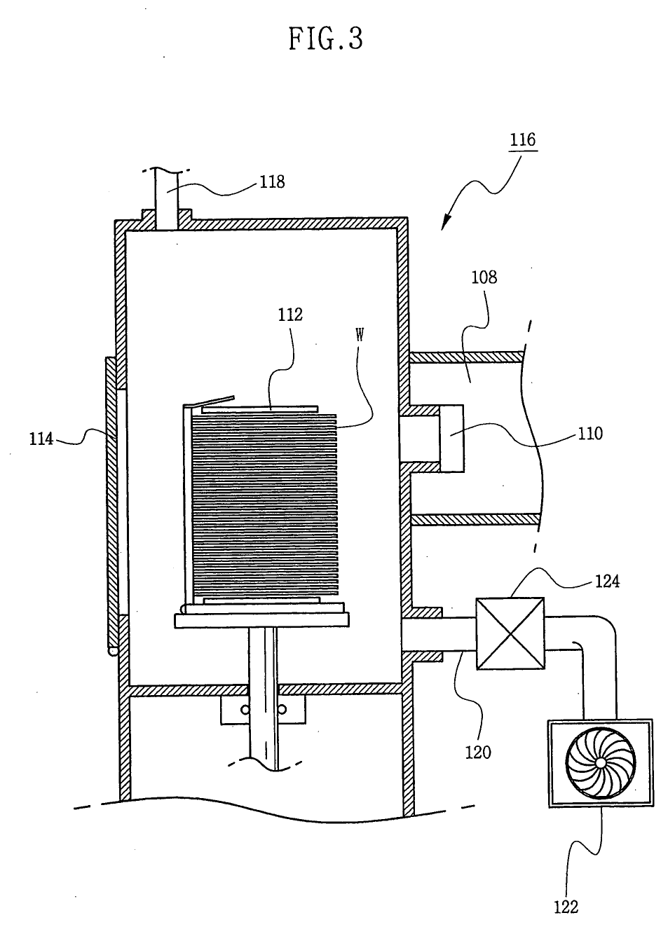

FIG. 2 illustrates a cluster type of semiconductor device manufacturing equipment 100 to which an isolation value unit is applied in accordance with an exemplary embodiment of the present invention, and FIG. 3 illustrates a detailed structure of a load lock chamber of FIG. 2. Referring to FIG. 2, a cluster type of semiconductor device manufacturing equipment 100 may include a plurality of process chambers 102 in which unit processes, such as a thin layer deposition process, an etching process etc., may be performed on at least one wafer W, an alignment chamber 104 for aligning a flat zone of the wafer W in one direction, a transfer chamber 108 in which a robotic arm 106 is provided for transferring the wafer W from the alignment chamber 104 to each of the process chambers 102, and a plurality of load lock chambers 116, each of which communicates with the transfer chamber 108 and is provided on one side thereof with a slit valve 110 opened when the robotic arm 106 enters therein, and provided on the other side thereof with a door 114 through which a wafer cassette 112, in which the plurality of wafers W are mounted, enters.

Referring to FIG. 3, each of the load lock chambers 116 may be provided on an upper portion thereof with a purge gas supply line 118 that is adapted to supply a purge gas, and on a lower portion thereof with an exhaust line 120 that is adapted to exhaust the purge gas supplied into each of the load lock chambers 116.

In the semiconductor device manufacturing equipment illustrated in FIGS. 2 and 3, each of the process chambers 102 may provide a hermetic space so that a unit process for manufacturing the semiconductor device can be performed. For example, various unit processes may be performed in the process chambers 102, such as a thin layer deposition process of forming a predetermined thickness of thin film on the wafer W through a physical vapor deposition method and/or a chemical vapor deposition method, or an etching process of removing a surface of the wafer W exposed though a mask layer, such as a photoresist layer, which is formed on the wafer W, etc. Further, after an etching process is completed, an ashing process of oxidizing and removing the photoresist layer may be performed. Typically, the thin layer deposition process, the etching process, and the ashing process each increase uniformity and reliability by converting a reaction gas having excellent reactivity into a plasma state and causing the converted reaction gas to flow onto the wafer W.

In each process chamber 102, it may be very important to minimize the inflow of contaminants, such as particles, in order to generate uniform plasma. To this end, the process chambers 102 may be maintained in a vacuum state using a vacuum pump. For example, when the wafer W is loaded, each of the process chambers 102 may be pumped to a high vacuum, e.g., about 1×10⁻⁶ Torr. Then, when supplied with a purge gas for inducing the plasma reaction, e.g., nitrogen (N₂), argon (Ar), etc., each of the process chambers 102 may be maintained in a low vacuum, e.g., between about 1×10⁻³ Torr and about 1×10⁻¹ Torr.

When the unit processes are completed in the process chambers 102 respectively, the slit valve 110 may be opened between each process chamber 102 and the transfer chamber 108 so that the robotic arm 106 can take the wafer W out of each process chamber 102. At this time, a level of vacuum of each process chamber 102 is set to be higher than that of the transfer chamber 108. Accordingly, air in the transfer chamber 108 is caused to flow into each process chamber 102. As a result, air in each process chamber 102 is prevented from flowing toward the transfer chamber 108, so that the contamination of the transfer chamber 108 may be reduced.

Subsequently, when the wafer W withdrawn by the robotic arm 106 is to be transferred into any one of the load lock chambers 116, the slit valve 110 between the load lock chamber 116 and the transfer chamber 108 may be opened. At this time, a degree of vacuum of the load lock chamber 116 may be set to be higher than that of the transfer chamber 108, so that air in the load lock chamber 116 is prevented from flowing toward and contaminating the transfer chamber 108.

The wafer W may be on standby in the wafer cassette 112 until the other wafers W received in the wafer cassette 112 are sequentially transferred and the semiconductor device manufacturing process is complete. At this time, a strong acid solution or other diffusive substance remaining on the wafer W may evaporate and be dispersed in the form of fumes, which may attach to inner walls of the load lock chambers 116. Such contaminants attached to the inner walls of the load lock chambers 116 can be later separated as loose particles, e.g., by an air stream or a momentary eddy in the load lock chambers 116. The particles may attach to the surface of a wafer W that is on standby in the load lock chambers 116, or a wafer W being transferred. As a result, a thin layer formed on the wafer W may be degraded or a subsequent process may fail. The particles in the load lock chambers 116 may be eliminated using the vacuum pump 122 connected via the exhaust line 120.

As described above, the purge gas supply line 118 supplied with the purge gas may be arranged on the upper portion of each of the load lock chambers 116, and the exhaust line 120 for exhausting the purge gas supplied into each of the load lock chambers 116 may be arranged on the lower portion of each of the load lock chambers 116. The doors 114 may be coupled to outer walls of the load lock chambers 116 respectively, and hermetically close the load lock chambers 116. Each load lock chamber 116 may be pumped via the exhaust line 120 provided on the lower portion of the load-lock chamber 116. For example, the load lock chambers 116 may be pumped to have a degree of vacuum of about 3×10⁻³ Torr. In addition, the vacuum pump 122 may cooperate with a dry pump or a rotary pump capable of pumping the load lock chamber 166 to a pressure of about 1×10⁻³ Torr.

Although not shown, each load lock chamber 116 may be provided with a vacuum sensor, which may be inserted from the outside to the inside through a port formed on a side wall of the load lock chamber 116. The vacuum sensor may sense the degree of vacuum of the load lock chamber 116. For example, the vacuum sensor may include a Baratron® gauge for measuring a degree of vacuum in comparison to a reference pressure using a baffle, or a Pirani gauge for measuring a degree of vacuum using a principle that a thermal conductivity of gas is substantially proportional to a degree of vacuum, i.e., a pressure of residual gas, under a low pressure.

The exhaust line 120 may be equipped with an isolation valve unit 124, which may receive the measured signal output from the vacuum sensor and which may regulated a flow of the air pumped by the vacuum pump 122 so as to allow the degree of vacuum of the load lock chamber 116 to be set to a predetermined level. Vacuum sensors may be disposed in each load lock chamber 116, at other suitable locations in the isolation valve unit 124 such as outputs of isolation valves, etc. The isolation valve unit 124 may control the vacuum state of the load lock chamber 116. The isolation valve unit 124 may hold the exhaust line 120 closed until the door 114 of the load lock chamber 116 is closed, and may open the exhaust line 120 once the door 114 is closed and the load lock chamber 166 is sealed off, so as to enable the air in the load lock chamber 116 to be pumped by the vacuum pump 122.

In this manner, when the air in the load lock chamber 166 is pumped to a predetermined level and the load lock chamber 166 reaches a preset degree of vacuum, a purge gas supply (not shown) may supply the load lock chamber 166 with the purge gas ranging from several sccm (standard cubic centimeters per minute) to several tens of sccm via the purge gas supply line 118 provided on the upper portion of the load lock chamber 116. The purge gas may cause particles, etc., in the load lock chamber 116 to be exhausted via the exhaust line 120, thereby preventing the contamination of the load lock chamber 116.

Each load lock chamber 116 may serve as a buffering chamber for maintaining the degree of vacuum of each process chamber 102, and may serve as a blockage area for preventing the process atmosphere of each process chamber 102 from being influenced by the outside. Thus, the purge gas may be supplied into the load lock chamber 116 via the purge gas supply line 118, the purge gas may be diluted with fumes evaporated and dispersed from the surface of the wafer, and the diluted purge gas may be exhausted to the outside via the exhaust line 120 by the pumping of the vacuum pump 122. The pumping of the vacuum pump 122 may enable contaminants such as particles to be eliminated from the load lock chamber 116, as well as maintaining a pressure level required for the process.

Conventionally, when the vacuum pump stops pumping the load lock chamber having a vacuum state, the isolation valve of the exhaust line connected between the load lock chamber and the vacuum pump is not rapidly closed. Hence, air flows into the load lock chamber having the vacuum state, so that a momentary eddy taken place. This eddy causes particles to be generated in the load lock chamber.

In contrast, according to this embodiment of the present invention, the isolation valve unit 124 may be provided for the exhaust line connected between the load lock chamber 116 and the vacuum pump 122. A structure of the isolation valve unit 124 according to an embodiment of the present invention will be described below in detail.

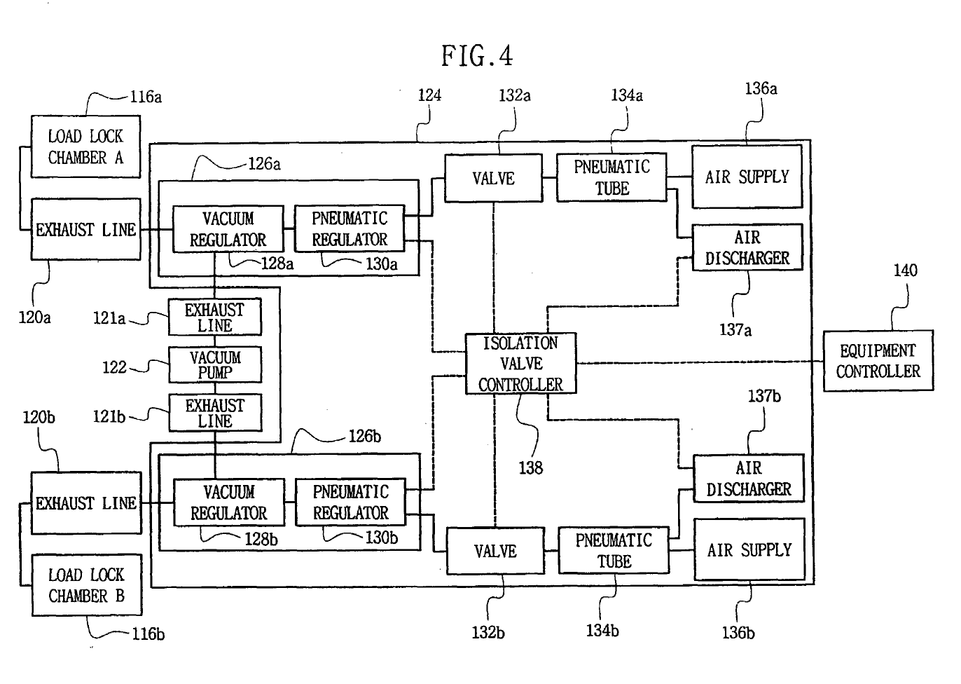

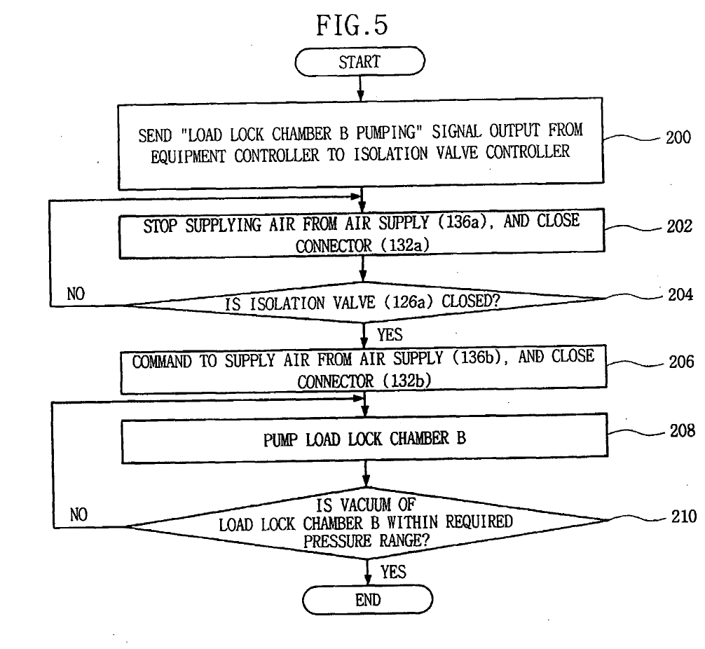

FIG. 4 illustrates a block diagram of an isolation valve unit 124 according to an exemplary embodiment of the present invention, in which the isolation valve unit 124 may control the opening and closing of exhaust lines connected to two or more load lock chambers. Two load lock chambers 116a and 116b connected to the exhaust lines and the isolation valve unit 124 are illustrated in FIG. 4. FIG. 5 illustrates a flowchart of a method of operating the isolation valve unit of FIG. 4. Operations illustrated in FIG. 5 will be referenced parenthetically.

Referring to FIG. 4, load lock chamber A 116a and load lock chamber B 116b may be connected to exhaust lines 120a and 120b, respectively.

The exhaust lines 120a and 120b may be connected to the isolation valve unit 124. The isolation valve unit 124 may include isolation valves 126a and 126b that are provided with vacuum regulators 128a and 128b, as well as well as pneumatic regulators 130a and 130b, for closing or opening the exhaust lines. The isolation valve unit 124 may further include valves 132a and 132b connected between the isolation valves 126a and 126b and the pneumatic tubes 134a and 134b. Additionally, the isolation valve unit 124 may include air supplies 136a and 136b and air dischargers 137a and 137b that are connected to the pneumatic tubes 134a and 134b, as well as an isolation valve controller 138 that is connected to the pneumatic regulators 130a and 130b, to the valves 132a and 132b, and to the air dischargers 137a and 137b. The isolation valve controller 138 may also be connected to an equipment controller 140.

Rear ends of the vacuum regulators 128a and 128b may be connected to the vacuum pump 122. The vacuum pump 122 may pump the load lock chambers 116a and 116b via exhaust lines 121a and 121b. The valves 132a and 132b may be connected to auxiliary components, e.g., joints or bends, etc. (not shown). In an implementation (not shown), the pneumatic tubes 134a and 134b may be directly connected to the pneumatic regulators 130a and 130b without the valves 132a and 132b. The isolation valves 126a and 126b may be implemented as, e.g., solenoid valves. It will be appreciated, however, that this implementation is merely an example, and may be suitably modified by one of skill in the art.

When the load lock chambers 116a and 116b are pumped, air supplied from the air supplies 136a and 136b reaches the pneumatic regulators 130a and 130b of the isolation valves 126a and 126b via the pneumatic tubes 134a and 134b and the valves 132a and 132b. The pneumatic regulators 130a and 130b may be opened by the air, and thereby the vacuum regulators 128a and 128b may also be opened. As a result, the isolation valves 126a and 126b may be opened. In this state, in which the isolation valves 126a and 126b are opened, the load lock chambers 116a and 116b may be pumped by the vacuum pump 122, thereby maintaining the load lock chambers 116a and 116b in a vacuum state.

When the load lock chambers 116a and 116b are not pumped, the air supplies 136a and 136b may stop supplying the air, and then the air supplied to the pneumatic tubes 134a and 134b may be exhausted via the air dischargers 137a and 137b. Thus, the air flowing though the pneumatic regulators 130a and 130b and the vacuum regulators 128a and 128b may be stopped, and thus the isolation valves 126a and 126b may be closed. Thereby, the exhaust lines 121a and 121b between the load lock chambers 116a and 116b and the vacuum pump 122 may be closed, so that the load lock chambers 116a and 116b are not pumped.

An exemplary process of operating the isolation valves 126a and 126b will now be described using a particular example of pumping the load lock chamber B 116b in the state where the load lock chamber A 116a maintains vacuum. Referring to FIGS. 4 and 5, a “load lock chamber B pumping” signal may be output from the equipment controller 140 to the isolation valve controller 138 (S200). The isolation valve controller 138 receiving the “load lock chamber B pumping” signal may stop the supply of air by the air supply 136a. This may be accomplished by closing the valve 132a (S202).

At this point, a check may be performed to determine whether or not the isolation valve 126a connected to the valve 132a is closed (S204). If the isolation valve 126a is not closed, the process may return to operation S202, and the state of the air supplied from the air supply 136a may be checked.

Once the isolation valve 126a is closed, a signal may be given to supply air from the air supply 136b to the load lock chamber B 116b. Air supplied from the air supply 136b may be supplied to the valve 132b via the pneumatic tube 134b. When the valve 132b is opened, the isolation valve 126b may also be opened (S206). When the isolation valve 126b is opened, the vacuum pump 122 may be placed into flow communication with the load lock chamber B 116b via the exhaust lines 120b and 121b. Thus, the load lock chamber B 116b may be pumped by the vacuum pump 122 (S208).

A check may be performed to determine whether or not the degree of vacuum inside the load lock chamber B 116b is within a required range (S210). If the degree of vacuum inside the load lock chamber B 116b is not within the required range, pumping of the load lock chamber B 116b may be continued.

After it is confirmed that the isolation valve 126a between the load lock chamber A 116a and the vacuum pump 122 is closed, the isolation valve 126b for pumping the load lock chamber B 116b may be opened. In other words, the closing of the isolation valve 126a connected to the load lock chamber A 116a may precede the opening of the isolation valve 126b connected to the load lock chamber B 116b. As a result, the external air of atmospheric pressure may be prevented from being introduced into the load lock chamber A 116a via the exhaust lines 120a and 121a, and thus it may be possible to prevent an eddy from being generated in the load lock chamber A 116a. By preventing the eddy, particles generated inside the load lock chamber A 116a may be kept to a minimum, thereby reducing or eliminating wafer loss, avoiding the decrease of the preventative maintenance period, etc.

After it is confirmed that the closing of the isolation valve 126a is completed, the operation for opening the isolation valve 126b may be performed. Thus, atmospheric pressure may be prevented from being introduced into the load lock chamber A 116a.

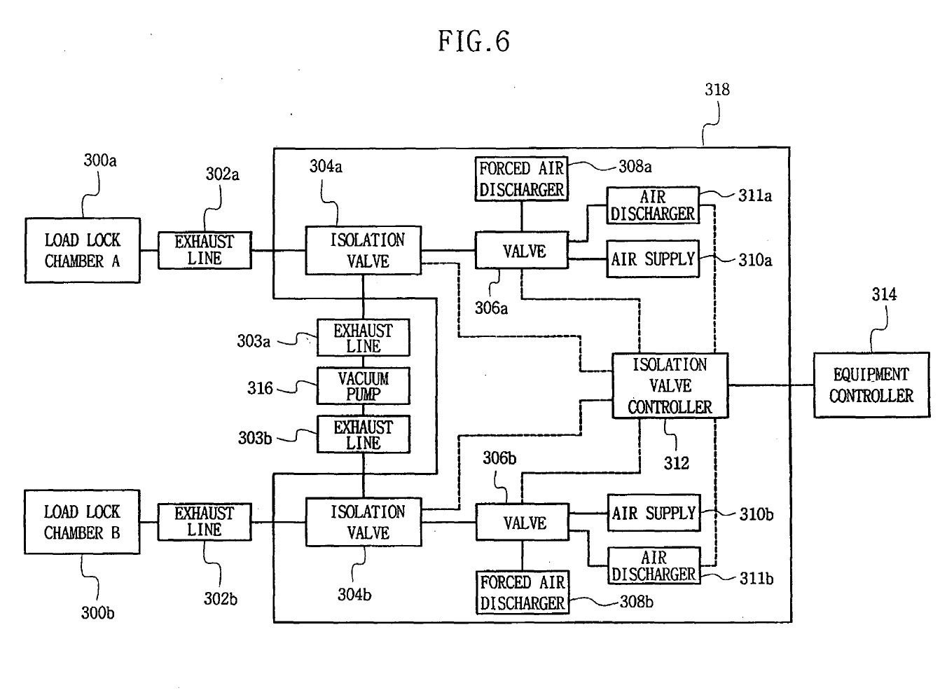

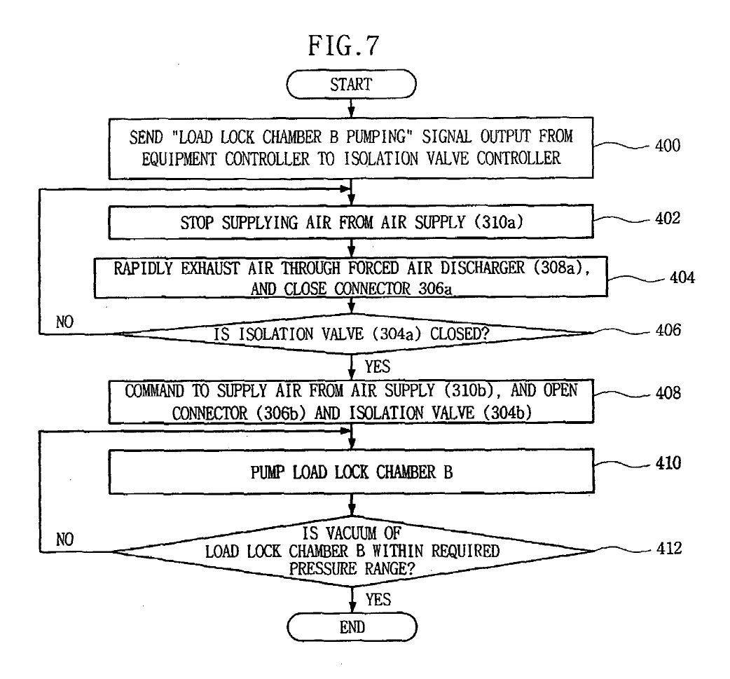

In the embodiment just described, the opening of the isolation valve 126b may be delayed, which may extend an overall process time. This delay may be reduced or eliminated according to another exemplary embodiment of the present invention. FIG. 6 illustrates a block diagram of an isolation valve unit 318 according to another exemplary embodiment of the present invention, and FIG. 7 illustrates a flowchart of a method of operating the isolation valve unit of FIG. 6. Operations of the method illustrated in FIG. 7 will be referred to parenthetically. Referring to FIG. 6, a load lock chamber A 300a and a load lock chamber B 300b may be connected to exhaust lines 302a and 302b, respectively. The exhaust lines 302a and 302b may be connected to the isolation valve unit 318.

The isolation valve unit 318 may include isolation valves 304a and 304b that close or open the exhaust lines. The isolation valve unit 318 may also include valves 306a and 306b between the isolation valves 304a and 304b, which control opening and closing of the isolation valves 304a and 304b using air supplied from air supplies 310a and 310b. The isolation valve unit 318 may further include forced air dischargers 308a and 308b, and air dischargers 311a and 311b, which are connected to the valves 306a and 306b. An isolation valve controller 312 may be connected to the isolation valves 304a and 304b, to the air dischargers 311a and 311b, to the valves 306a and 306b, and to an equipment controller 314. Rear ends of the isolation valves 304a and 304b may be connected to a vacuum pump 316 for pumping the load lock chambers 300a and 300b to a predetermined degree of vacuum via exhaust lines 303a and 303b.

The forced air dischargers 308a and 308b may help rapidly discharge air existing between the isolation valves 304a and 304b and the valves 306a and 306b once the supply of air from the air supplies 310a and 310b has been stopped. When the air existing between the isolation valves 304a and 304b and the valves 306a and 306b is forcibly discharged, an air discharge speed may be significantly increased as compared to the case in which the air is discharged without forcible discharge. The valves 306a and 306b may close rapidly and thus the isolation valves 304a and 304b may also be rapidly closed. As a result, atmospheric pressure air may be prevented from being introduced into the load lock chambers 300a and 300b while they are maintained in a vacuum state.

The forced air dischargers 308a and 308b may be connected to the valves 306a and 306b. In another implementation, they may be connected to a section between the isolation valves 304a and 304b and the valves 306a and 306b.

In an implementation (not shown), the valves 306a and 306b may be omitted. Without the valves 306a and 306b, the forced air dischargers 308a and 308b may be directly connected to the rear ends of the isolation valves 304a and 304b. The isolation valves 304a and 304b may be implemented as, for instance, solenoid valves. However, it will be appreciated that this construction is merely an example and may be suitably modified by one of skill in the art.

When the load lock chambers 300a and 300b are pumped, air is supplied from the air supplies 310a and 310b when the valves 306a and 306b are open. The opening of the valves 306a and 306b causes the isolation valves 304a and 304b to open. When the isolation valves 304a and 304b are open, the load lock chambers 300a and 300b are pumped using the vacuum pump 316, thereby maintained them in a vacuum state. In contrast, when the load lock chambers 300a and 300b are not pumped, the air supplies 310a and 310b stop supplying the air, and then the air is exhausted via the air dischargers 311a and 311b.

Air between the isolation valves 304a and 304b and the valves 306a and 306b is forced to be rapidly discharged through the forced air dischargers 308a and 308b connected to the valves 306a and 306b, so that the valves 306a and 306b may be closed more rapidly. By rapidly closing the valves 306a and 306b, the isolation valves 304a and 304b may also be closed more rapidly, and thus the air flowing between the load lock chambers 300a and 300b and the vacuum pump 316 via the exhaust lines 302a, 303a, 302b, and 303b may be interrupted. Thus, the load lock chambers 300a and 300b are not pumped.

An embodiment of the present invention will now be described with reference to an exemplary operation of the isolation valves 304a and 304b, wherein the load lock chamber B 300b is pumped while the load lock chamber A 300a maintains a predetermined degree of vacuum. Referring to FIGS. 6 and 7, a “load lock chamber B pumping” signal may be output from the equipment controller 314 to the isolation valve controller 312 (S400). The isolation valve controller 312, upon receiving the “load lock chamber B pumping” signal, may stop the supply of air from the air supply 310a (S402). Stopping the supply of air from the air supply 310a may be accomplished by closing the valve 306a.

Air existing between the isolation valve 304a and the valve 306a may be rapidly discharged through the forced air discharger 308a so that the valve 306a may be rapidly (S404). By connecting the forced air discharger 308a to the valve 306a, the air existing between the isolation valve 304a and the valve 306a may be more rapidly exhausted than through natural exhaust. Thus, the valve 306a may be closed more rapidly, and the isolation valve 304a may also be closed more rapidly.

A check may be performed to determine whether or not the isolation valve 304a is fully closed (S406). If the isolation valve 304a is not closed, the process may return to operation S402, and the state of the air supplied by the air supply 310a to the side of the load lock chamber A 300a may be checked.

Once the isolation valve 304a is closed, a signal may be given to supply the air from the air supply 310b. The air may be supplied from the air supply 310b via the valve 306b. When the valve 306b is opened, the isolation valve 304b may also be opened (S408). As the isolation valve 304b is opened, the vacuum pump 316 is interconnected to the load lock chamber B 300b via the exhaust lines 302b and 303b. Thus, the load lock chamber B 300b may be pumped using the vacuum pump 316 (S410).

A check may be performed to determine whether or not the vacuum inside the load lock chamber B 300b is within a range required for the process (S412). If the vacuum inside the load lock chamber B 300b is not within the required range, the pumping of the load lock chamber B 300b may be continued.

According to another exemplary embodiment of the present invention, the isolation valve controller 312 receiving the “load lock chamber B pumping” signal may stop the supply of air from the air supply 310a and rapidly exhaust the air existing between the isolation valve 304a and the valve 306b through the forced air discharger 308a at the same time. In this embodiment, when the air existing between the isolation valve 304a and the valve 306b is exhausted through the forced air discharger 308a, two exhaust processes, a natural exhaust process forced exhaust process, may be performed. Thus, the closing speeds of the valve 306a and its cooperating isolation valve 304a may be significantly enhanced as compared to the natural exhaust process alone.

As illustrated in FIG. 7, operations S402 through S410 may be sequentially performed. Even if operations S402 through S410 are sequentially performed, the valve 306a may be rapidly closed due to the forced air discharger 308a. Accordingly, it may be possible to reduce the time delay of opening the isolation valve 304b connected to the load lock chamber B 300b.

In another implementation, operations S402 through S410 may be performed at the same time. In particular, the “load lock chamber B pumping” signal output from the equipment controller 314 may be sent to the isolation valve controller 312. The isolation valve controller 312 receiving the “load lock chamber B pumping” signal may stop the supply of air from the air supply 310a, and may simultaneously signal the air supply 310b to supply air. The supply of air through the valve 306a may be stopped, and simultaneously the remaining air existing between the isolation valve 304a and the valve 306a may be rapidly exhausted through the forced air discharger 308a. Thus, the valve 306a and its cooperating isolation valve 304a may be closed.

In this configuration, the supply of air from the air supply 310a may be interrupted, while simultaneously air is supplied from the air supply 310b. As a result, the valve 306a and isolation valve 304a for the load lock chamber A 300a may be closed, while simultaneously the valve 306b and isolation valve 304b for the load lock chamber B 300b may be opened.

In this manner, the isolation valve 304a may be adapted to be rapidly closed, so that it is possible to solve the conventional problem that the air existing in the exhaust lines 302a and 303a at an atmospheric pressure is introduced into the load lock chamber A 300a while it is in a vacuum state, which could generate an eddy. Further, the valve 306a and isolation valve 304a for the load lock chamber A 300a are adapted to be closed, and simultaneously the valve 306b and isolation valve 304b for the load lock chamber B 300b are adapted to be opened, so that a delay in time depending on the opening and closing between the isolation valves 304a and 304b can be reduced.

As set forth above, in the present invention, the closing of the isolation valve for the load lock chamber that is in a vacuum state may precede the opening of the isolation valve for the load lock chamber that is in a non-vacuum state. Thus, it may be possible to prevent an eddy from being generated inside the load lock chamber of the vacuum state, thereby minimizing the particles generated inside the load lock chamber that is in the vacuum state. Thus, it may be possible to avoid conventional problems such as wafer loss, a decrease in the preventative maintenance period, etc., while improving the reliability and yield of the fabricated semiconductor devices.

Forced air dischargers may be connected to valves that control the isolation valves, which may enable a more rapid closing the isolation valves. As a result, the delay in time depending on the opening and closing of the isolation valves can be reduced, and thus the efficiency of process may be enhanced.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A vacuum apparatus, comprising:
a first isolation chamber;
a second isolation chamber;
a vacuum source configured to extract air from the first and second isolation chambers; and
an isolation valve unit, wherein the isolation valve unit is configured to close a flow path between the vacuum source and the first isolation chamber before opening a flow path between the vacuum source and the second isolation chamber when the first isolation chamber is in a vacuum state and the second isolation chamber is at a pressure higher than that of the first isolation chamber.

2. The vacuum apparatus as claimed in claim 1, wherein the vacuum source is connected to the first and second isolation chambers by exhaust lines, and the isolation valve unit includes:
isolation valves configured to open and close the exhaust lines;
an isolation valve controller for controlling the opening and closing of the isolation valves;
air supplies configured to supply air to the isolation valves according to an isolation valve opening signal from the isolation valve controller; and
air dischargers configured to exhaust the air supplied to the isolation valves according to an isolation valve closing signal from the isolation valve controller.

3. The vacuum apparatus as claimed in claim 2, wherein the isolation valves include:
pneumatic regulators that are opened and closed by air from the air supplies, and
vacuum regulators that are opened and closed according to whether the pneumatic regulators are opened and closed, respectively.

4. The vacuum apparatus as claimed in claim 3, wherein the air supplies and the air dischargers are connected to the pneumatic regulators via valves.

5. The vacuum apparatus as claimed in claim 4, wherein the valves are solenoid valves that are configured to alternately provide and block air from the air supplies to the pneumatic regulators.

6. The vacuum apparatus as claimed in claim 5, wherein signal lines connect the isolation valve controller to the valves, and
the valves alternately provide and block air from the air supplies in correspondence with signals provided by the isolation valve controller.

7. The vacuum apparatus as claimed in claim 3, further comprising forced air dischargers configured to forcibly exhaust air existing between the isolation valves and the air supplies according to the isolation valve closing signal.

8. The vacuum apparatus as claimed in claim 7, wherein the air supplies and the air dischargers are connected to the pneumatic regulators via valves, and
the forced air dischargers are connected to the valves.

9. The vacuum apparatus as claimed in claim 3, wherein signal lines connect the isolation valve controller to the pneumatic regulators.

10. The vacuum apparatus as claimed in claim 3, wherein signal lines connect the isolation valve controller to the isolation valves, the air dischargers, and valves disposed between the air supplies and respective isolation valves.

11. The vacuum apparatus as claimed in claim 1, wherein the isolation chambers are load lock chambers.

12. A method of operating a semiconductor device manufacturing equipment having a vacuum apparatus that includes a plurality of chambers having different pressure states, the method comprising:
closing a first exhaust line connected to a first chamber having a degree of vacuum higher than that of the other chambers among the plurality of chambers; and
after the closing of the first exhaust line, opening a second exhaust line connected to a second chamber having a pressure higher than that of the first chamber.

13. The method as claimed in claim 12, further comprising checking a closed state of the first exhaust line.

14. The method as claimed in claim 12, wherein the closing of the first exhaust line includes:
providing a close signal from an isolation valve controller to a first valve, the close signal causing the first valve to stop a supply of air from a first air supply to a first isolation valve so as to cause the first isolation valve to close the first exhaust line.

15. The method as claimed in claim 14, wherein the closing of the first exhaust line further includes forcibly exhausting air from the first valve using a first forced air discharger connected to the first valve.

16. The method as claimed in claim 14, wherein the opening of the second exhaust line includes:
supplying air from a second air supply to a second valve; and
using the air from the second air supply to open the second valve between the second air supply and a second isolation valve so as to cause the second isolation valve to open the second exhaust line.

17. A method of operating a semiconductor device manufacturing equipment having a vacuum apparatus that includes a plurality of chambers having different pressure states, the method comprising simultaneously performing:
closing a first exhaust line connected to a first chamber having a degree of vacuum higher than that of the other chambers among a plurality of chambers; and
opening a second exhaust line connected to a second chamber having a pressure higher than that of the first chamber.

18. The method as claimed in claim 17, wherein the closing of the first exhaust line connected to the first chamber comprises:
stopping a supply of air from a first air supply to a first isolation valve;
using a first forced air discharger to forcibly exhaust air inside a first valve provided between the first air supply and the first isolation valve; and
closing the first valve to as to cause the first isolation valve to close the first exhaust line.

19. The method as claimed in claim 18, wherein the opening of the second exhaust line includes:
supplying air from a second air supply to a second valve; and
using the air from the second air supply to open the second valve between the second air supply and a second isolation valve so as to cause the second isolation valve to open the second exhaust line.
